(19) United States
(12) Patent Application Publication
(10) Pub. No.: US 2025/0354257 A1
(43) Pub. Date: Nov. 20, 2025

(54) SURFACE COATED CUTTING TOOLS

(71) Applicant: KENNAMETAL INC., Latrobe, PA (US)

(72) Inventor: Kimaya Vyavhare, Latrobe, PA (US)

(21) Appl. No.: 18/666,271

(22) Filed: May 16, 2024

(51) Int. Cl. C23C 16/40; B23B 27/14; C23C 16/34; C23C 16/36

(52) U.S. Cl. CPC C23C 16/403; B23B 27/148; C23C 16/34; C23C 16/36; B23B 2228/105

(57) ABSTRACT

In one aspect, cutting tools are described herein comprising wear resistant coatings employing one or more refractory layers of polycrystalline α-Al₂O₃. Briefly, a coated cutting tool described herein comprises a substrate, and a coating adhered to the substrate, the coating comprising a layer of polycrystalline α-Al₂O₃ deposited by chemical vapor deposition (CVD), the polycrystalline α-Al₂O₃ layer having a length of Σ3 type of grain boundaries as measured using electron backscatter diffraction (EBSD) more than 0% but less than 10% of the total length of all grain boundaries and having texture coefficients (TC) greater than 6 for the (006) growth direction and greater than 5 for the (0 0 12) growth direction.

### FIELD

The present invention relates to refractory coatings and, in particular, to refractory coatings deposited by chemical vapor deposition (CVD) for cutting tool and/or metal removal applications.

### BACKGROUND

Cutting tools, including cemented carbide cutting tools, have been used in both coated and uncoated conditions for machining various metals and alloys. In order to increase cutting tool wear resistance, performance and lifetime, one or more layers of refractory material have been applied to cutting tool surfaces. TiC, TiCN, TiN and/or Al₂O₃, for example, have been applied to cemented carbide substrates by CVD and by physical vapor deposition (PVD). While effective in inhibiting wear and extending tool lifetime in a variety of applications, refractory coatings based on single or multi-layer constructions of the foregoing refractory materials have increasingly reached their performance limits, thereby calling for the development of new coating architectures for cutting tools.

### SUMMARY

In one aspect, cutting tools are described herein comprising wear resistant coatings employing one or more refractory layers of polycrystalline α-Al₂O₃. Briefly, a coated cutting tool described herein comprises a substrate, and a coating adhered to the substrate, the coating comprising at least one layer of polycrystalline α-Al₂O₃ deposited by chemical vapor deposition (CVD), the polycrystalline α-Al₂O₃ layer having a length of 23 type of grain boundaries as measured using electron backscatter diffraction (EBSD) more than 0% but less than 10% of the total length of all grain boundaries and having texture coefficients (TC) greater than 6 for the (006) growth direction and greater than 5 for the (0 0 12) growth direction, the texture coefficients being defined as:

$$TC ( hkl ) = \frac{I ( hkl )}{{I}_{o} ( hkl )} {\{ \frac{1}{n} \sum \frac{I ( hkl )}{{I}_{o} ( hkl )} \}}^{- 1}$$

where
I(hkl)=measured intensity of the (hkl) reflection
Iₒ(hkl)=standard intensity of the (hkl) reflection according to International Center for Diffraction Data (ICDD) card 43-1484
n=number of reflections used in the TC calculation
(hkl) reflections used in the TC calculation are:
(012), (104), (110), (006), (113), (202), (024) and (116) to calculate TC (006) or
(012), (104), (110), (113), (116), (300) and (0 0 12) to calculate TC (0012).

In some embodiments, the polycrystalline α-Al₂O₃ layer comprises columnar grains exhibiting an average grain width less than 5 μm. Average grain width, in some embodiments, is less than 3 μm, such as 0.5 μm to 2.5 μm. Additionally, in some embodiments, at least 5% of all grain boundaries in the polycrystalline α-Al₂O₃ layer have a misorientation angle less than 15degrees as determined using a field-emission scanning electron microscope (FESEM) and an electron backscatter diffraction (EBSD) detector. In some embodiments, the misorientation angle is less than 10 degrees or less than 5 degrees. Moreover, in some embodiments, 5% to 20% of all grain boundaries in the polycrystalline α-Al₂O₃ layer have a misorientation of 2-5 degrees and at least 5% or at least 6% of all grain boundaries in the polycrystalline α-Al₂O₃ layer have a misorientation of greater than 5 degrees up to 15 degrees. In some embodiments, for example, 16-20% of all grain boundaries of polycrystalline α-Al₂O₃ layer have a misorientation of 2-5 degrees.

In another aspect, methods of making coated cutting tools comprising one or more refractory layers of polycrystalline α-Al₂O₃ are described herein. In some embodiments, a method comprises depositing a polycrystalline α-Al₂O₃ layer from a gaseous reaction mixture comprising H₂, CO, CO₂, H₂S, HCl, AlCl₃ wherein the volume ratio of CO₂ and H₂S in the CVD reaction chamber lies within the range of 5<CO₂/H₂S<10, and the deposited polycrystalline α-Al₂O₃ layer has a length of Σ3 type of grain boundaries as measured using EBSD more than 0% but less than 10% of the total length of all grain boundaries and having texture coefficients (TC) greater than 6 for the (006) growth direction and greater than 5 for the (0 0 12) growth direction as set forth above.

These and other embodiments are further described in the following detailed description.

### BRIEF DESCRIPTION OF THE DRAWINGS

FIG. 1 illustrates measuring average α-Al₂O₃ grain width according to the method described herein.

### DETAILED DESCRIPTION

Embodiments described herein can be understood more readily by reference to the following detailed description and examples and their previous and following descriptions. Elements, apparatus and methods described herein, however, are not limited to the specific embodiments presented in the detailed description and examples. It should be recognized that these embodiments are merely illustrative of the principles of the present invention. Numerous modifications and adaptations will be readily apparent to those of skill in the art without departing from the spirit and scope of the invention.

In one aspect, cutting tools are described herein comprising refractory coatings employing one or more polycrystalline α-Al₂O₃ layers having grain boundary architectures advantageous for resisting various degradative mechanisms including cracking and/or flaking. Accordingly, cutting tools having such refractory coatings, in some embodiments, are suitable for high wear and/or abrasion applications, such as metal cutting operations. Turning now to specific components, a coated article comprises a substrate. A coated article can comprise any substrate not inconsistent with the objectives of the present invention. For example, a substrate can be a cutting tool or tooling used in wear applications. Cutting tools include, but are not limited to, cutting inserts (indexable and non-indexable), end mills or drills. Indexable cutting inserts can have any desired ANSI standard geometry for milling or turning applications. Substrates of coated articles described herein can be formed of cemented carbide, carbide, ceramic, cermet, steel or other alloy. A cemented carbide substrate, in some embodiments, comprises tungsten carbide (WC). WC can be present in a cutting tool substrate in an amount of at least about 80 weight percent or in an amount of at least about 85 weight percent. Additionally, metallic binder of cemented carbide can comprise cobalt or cobalt alloy. Cobalt, for example, can be present in a cemented carbide substrate in an amount ranging from 1 weight percent to 15 weight percent. In some embodiments, cobalt is present in a cemented carbide substrate in an amount ranging from 5-12 weight percent or from 6-10 weight percent. Further, a cemented carbide substrate may exhibit a zone of binder enrichment beginning at and extending inwardly from the surface of the substrate.

Cemented carbide substrates can also comprise one or more additives such as, for example, one or more of the following elements and/or their compounds: titanium, niobium, vanadium, tantalum, chromium, zirconium and/or hafnium. In some embodiments, titanium, niobium, vanadium, tantalum, chromium, zirconium and/or hafnium form solid solution carbides with WC of the substrate. In such embodiments, the substrate can comprise one or more solid solution carbides in an amount ranging from 0.1-5 weight percent. Additionally, a cemented carbide substrate can comprise nitrogen.

As described above, the coating adhered to the substrate comprises a layer of polycrystalline α-Al₂O₃ deposited by CVD, the polycrystalline α-Al₂O₃ layer having a length of Σ3 type of grain boundaries as measured using EBSD more than 0% but less than 10% of the total length of all grain boundaries and having texture coefficients (TC) greater than 6 for the (006) growth direction and greater than 5 for the (0 0 12) growth direction, the texture coefficients being defined as:

$$TC ( hkl ) = \frac{I ( hkl )}{{I}_{o} ( hkl )} {\{ \frac{1}{n} \sum \frac{I ( hkl )}{{I}_{o} ( hkl )} \}}^{- 1}$$

where
I(hkl)=measured intensity of the (hkl) reflection
Iₒ(hkl)=standard intensity of the (hkl) reflection according to International Center for Diffraction Data (ICDD) card 43-1484
n=number of reflections used in the TC calculation
(hkl) reflections used in the TC calculation are:
(012), (104), (110), (006), (113), (202), (024) and (116) to calculate TC (006) or
(012), (104), (110), (113), (116), (300) and (0 0 12) to calculate TC (0012).

The XRD peak data for calculation of the TC (006) and TC (0 0 12) is measured on a Bragg focusing diffractometer.

### Incidence Optics Included

Long fine focus X-ray tube operating at 45 KV and 40 MA.

Variable divergence optic operating in automatic mode to insure constant irradiated sample volume throughout the analysis.

Fixed antiscatter slit

### Receiving Optics Included

Variable Antiscatter slit operating in automatic mode to match the automatic divergence slit Multistrip solid state detector operating in scanning mode.

Scan parameters (speed and count time) are selected to insure a minimum of ten data steps across the peak full width at half max (FWHM) and approximately 10,000 total counts on the most intense peak. Collected data is first converted from variable mode to fixed mode usable for analysis. This conversion is completed using the formula:

$${I}_{FIX} ( θ , a ) = {I}_{ADS} ( θ , L ) \times ( \frac{R sin ( a / 2 )}{L} ) \times ( \frac{1}{sin ( θ + a / 2 )} + \frac{1}{sin ( θ - a / 2 )} )$$

where a=the divergence angle and L=the irradiated length on the sample The corrected intensity is analyzed using peak finding software to identify the peak position of all peaks in the collected data. The peaks are then refined using a profile function to precisely identify the peak position and peak height. This peak data is used for the alumina texture coefficient analysis. Due to the complexity of the CVD coating architecture, a thickness correction for the peak intensity was not applied.

As described herein, the polycrystalline α-Al₂O₃ layer has a length of Σ3 type of grain boundaries as measured using EBSD more than 0% but less than 10% of the total length of all grain boundaries. In some embodiments, the length of Σ3 type of grain boundaries is 1% to 8%, 2% to 6%, or 2% to 5% of the total length of all grain boundaries. For the EBSD measurement/analysis, a cross-sectional area of the coated tool was polished to a mirror finish. In this case, a colloidal silica was used, although diamond paste, ion milling, and other methods are acceptable. The prepared surface was observed using a field-emission scanning electron microscope (FESEM) and an EBSD detector. With the FESEM, an electron beam at an acceleration voltage of 25kV irradiated the polished surface, which was inclined to 70° with respect to the incident electron beam, to measure orientation angles of the hexagonal alumina crystal grains based on the collected Kikuchi diffraction patterns. Data was collected from an area of approximately 20 μm×80 μm, with a step size of 0.1 μm. Data processing was done using a commercially available software to determine the coincident site lattice (CSL) grain boundaries, including the 23 grain boundaries.

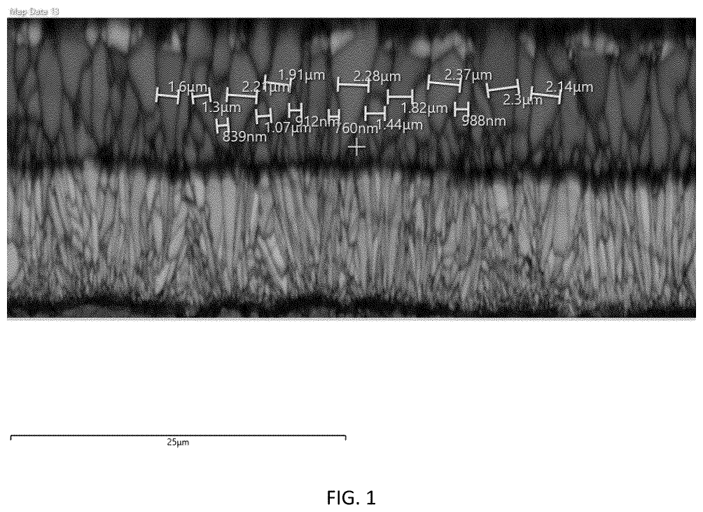

Grains of the polycrystalline α-Al₂O₃ layer, in some embodiments, can exhibit a columnar morphology with the long axis normal or substantially normal to the substrate. The columnar grains, in some embodiments, can exhibit an average grain width less than 5 μm. Average grain width, in some embodiments, is less than 3 μm, such as 0.5 μm to 2.5 μm. In some embodiments, average grain width is 0.5-4.5 μm or 1-3 μm. Average grain width is an average of the width of 25 consecutive grains of the polycrystalline α-Al₂O₃ layer measured on the polished cross-section of the polycrystalline α-Al₂O₃ layer using band contrast EBSD imaging. FIG. 1 illustrates measuring average α-Al₂O₃ grain width according to the method described herein. Alumina grain width was determined by using the caliper function on the EBSD band contrast maps in the data collection software. Measurements were taken from approximately 20 adjacent grains in the center of the coating layer. The measurements from the caliper function are based on the SEM magnification and internal calibrations in the software.

Additionally, in some embodiments, at least 5% of all grain boundaries in the polycrystalline α-Al₂O₃ layer have a misorientation angle less than 15 degrees as determined using a field-emission scanning electron microscope (FESEM) and an electron backscatter diffraction (EBSD) detector. In some embodiments, the misorientation angle is less than 10 degrees or less than 5 degrees. Moreover, in some embodiments, 5% to 20% of all grain boundaries in the polycrystalline α-Al₂O₃ layer have a misorientation of 2-5 degrees and at least 5% or at least 6% of all grain boundaries in the polycrystalline α-Al₂O₃ layer have a misorientation of greater than 5 degrees up to 15 degrees. In some embodiments, for example, 16-20% of all grain boundaries of polycrystalline α-Al₂O₃ layer have a misorientation of 2-5 degrees.

Grain boundaries of polycrystalline α-Al₂O₃ layer, in some embodiments, are tilt boundaries or twist boundaries. In some embodiments, the grain boundaries are a mixture of tilt and twist boundaries. When a mixture is present, the majority of the grain boundaries are tilt boundaries, in some embodiments.

Grain boundaries are characterized by 5 rotational and 3 translational parameters. All these parameters influence the properties of boundaries. The 3 translational parameters describe atomic shifts that may occur at grain boundaries. The rotational parameters are the 3 parameters describing the misorientation between the crystals and 2 parameters describing the grain boundary normal. The misorientation itself is a rotation consisting of a rotation axis (2 parameters) and a rotation angle (1 parameter). Usually, when the rotation angle is small (˜<15°) the grain boundary is composed of individual dislocations and the boundary is called is small/low angle grain boundary. When the angle is larger, the boundary structure is less well defined and it called a large angle grain boundary.

Grain boundaries and their characteristic rotational parameters can be observed, for example, by 2D and 3D EBSD or by TEM. The atomic parameters can be observed only by atomic resolution TEM.

In crystalline materials, the orientation of a crystallite is defined by a transformation from a sample reference frame (i.e. defined by the direction of a rolling or extrusion process and two orthogonal directions) to the local reference frame of the crystalline lattice, as defined by the basis of the unit cell. In the same way, misorientation is the transformation necessary to move from one local crystal frame to some other crystal frame. That is, it is the distance in orientation space between two distinct orientations. If the orientations are specified in terms of matrices of direction cosines gA and gB, then the misorientation operator ΔgAB going from A to B can be defined as follows:

$${g}_{B} = Δ {g}_{AB} {g}_{A}$$

$$Δ {g}_{AB} = {g}_{B} {g}_{A}^{- 1}$$

where the term g⁻¹ A is the reverse operation of gA, that is, transformation from crystal frame A back to the sample frame. This provides an alternate description of misorientation as the successive operation of transforming from the first crystal frame (A) back to the sample frame and subsequently to the new crystal frame (B).

Various methods can be used to represent this transformation operation, such as: Euler angles, Rodrigues vectors, axis/angle (where the axis is specified as a crystallographic direction), or unit quaternions. EBSD is well suited to extract this type of information as it gives both statistical and spatial information about the grain boundaries. The pattern consists of straight bright bands, so called Kikuchi bands, which have a direct relation to the lattice planes of the diffracting crystal: the centre line of each of the bands directly corresponds to the gnomonic projection of the lattice planes. The width of the Kikuchi band is approximately proportional to the Bragg angle of electron diffraction on the related lattice plane. The band intensity profile corresponds to the dynamic electron diffraction intensity obtained in a rocking experiment across the related lattice plane.

From the geometry of the Kikuchi bands in the pattern, the crystallographic phase and orientation can be determined. The band profiles contain information on the local defect densities (in particular on dislocation densities). This information can be obtained in a highly automated manner by computer software which then displays the basis of so called EBSD-based orientation microscopy (ORM).

Grain boundary misorientation in the polycrystalline α-Al₂O₃ can be determined according to the following protocol. A cross-sectional area of the coated tool is polished to a mirror finish. Colloidal silica is a suitable polishing agent, although diamond paste, ion milling, and other methods are acceptable. The prepared surface is observed using a field-emission scanning electron microscope (FESEM) and an electron backscatter diffraction (EBSD) detector. With the FESEM, an electron beam at an acceleration voltage of 25 kV irradiated the polished surface, which was inclined to 70° with respect to the incident electron beam, to measure orientation angles of the hexagonal alumina crystal grains based on the collected Kikuchi diffraction patterns. Data is collected from an area of approximately 20 μm×80 μm, with a step size of 0.1 μm. Data processing is done using a commercially available software for the FESEM/EBSD apparatus to determine a misorientation angle. Misorientation angles of <2° were discarded as possible strain within an individual grain, while grain boundaries were identified by misorientation angles >2°. An average over 3 EBSD maps is taken to arrive at the misorientation values.

Further, the alumina phase can exhibit low residual tensile stress in the as-deposited state. In some embodiments, the alumina phase has a residual tensile stress of 100-500 MPa or 20-400 MPa in the as-deposited state. Residual stress of the alumina phase can be determined using the Chi tilt Sin²ψ method with reference to the (116) reflection. For the alumina phase analysis, Poisson's Ratio ( [symbol] ) was set to 0.19, and the elastic modulus (E in GPa) was determined to be 415 from analysis of a single phase α-alumina coating by nanoindentation hardness. Additionally, the polycrystalline α-Al₂O₃ layer can have any desired thickness. In some embodiments, the polycrystalline α-Al₂O₃ layer has a thickness of 1-20 μm or 5-15 μm.

The polycrystalline α-Al₂O₃ layer can be deposited directly on the substrate surface. Alternatively, a coating described herein can further comprise one or more inner layers between the polycrystalline α-Al₂O₃ layer and the substrate. Inner layer(s), in some embodiments, comprise one or more metallic elements selected from the group consisting of aluminum and metallic elements of Groups IVB, VB and VIB of the Periodic Table and one or more non-metallic elements selected from Groups IIIA, IVA, VA and VIA of the Periodic Table. In some embodiments, one or more inner layers between the substrate and multiphase refractory layer comprise a carbide, nitride, carbonitride, oxycarbonitride, oxide or boride of one or more metallic elements selected from the group consisting of aluminum and metallic elements of Groups IVB, VB and VIB of the Periodic Table.

For example, one or more inner layers are selected from the group consisting of titanium nitride, titanium carbonitride, titanium oxycarbonitride, titanium carbide, zirconium nitride, zirconium carbonitride, hafnium nitride, hafnium carbonitride, TiAlₓSi_{y}CᵥN, and aluminum oxynitirde. Further, a layer of titanium oxycarbonitride can be employed as a bonding layer for the refractory layer and inner layers of the coating. Inner layer(s) of the coating can have any thickness not inconsistent with the objectives of the present invention. In some embodiments, a single inner layer can have a thickness of at least 1.5 μm. Alternatively, a plurality of inner layers can collectively achieve thickness of at least 1.5 μm.

The polycrystalline α-Al₂O₃ layer can be the outermost layer of the coating. Alternatively, a coating described herein can comprise one or more outer layers over the polycrystalline α-Al₂O₃ layer. Outer layer(s) can comprise one or more metallic elements selected from the group consisting of aluminum and metallic elements of Groups IVB, VB and VIB of the Periodic Table and one or more non-metallic elements selected from Groups IIIA, IVA, VA and VIA of the Periodic Table. Outer layer(s) over the polycrystalline α-Al₂O₃ layer can comprise a carbide, nitride, carbonitride, oxycarbonitride, oxide or boride of one or more metallic elements selected from the group consisting of aluminum and metallic elements of Groups IVB, VB and VIB of the Periodic Table. For example, one or more outer layers are selected from the group consisting of titanium nitride, titanium carbonitride, titanium oxycarbonitride, titanium carbide, zirconium nitride, zirconium carbonitride, hafnium nitride, hafnium carbonitride, alumina, TiAlₓSi_{y}CᵥN, aluminum oxynitirde, and combinations thereof.

Outer layers of coatings described herein can have any thickness not inconsistent with the objectives of the present invention. A coating outer layer, in some embodiments, can have a thickness ranging from 0.2 μm to 5 μm.

Coatings described herein can be subjected to post-coat treatments. Coatings, for example, can be blasted with various wet and/or dry particle compositions. Post coat blasting can be administered in any desired manner. In some embodiments, post coat blasting comprises shot blasting or pressure blasting. Pressure blasting can be administered in a variety of forms including compressed air blasting, wet compressed air blasting, pressurized liquid blasting, wet blasting and steam blasting. Wet blasting, for example, is accomplished using a slurry of inorganic and/or ceramic particles, such as alumina, and water. The particle slurry can be pneumatically projected at a surface of the coated cutting tool body to impinge on the surface of the coating. The inorganic and/or ceramic particles can generally range in size between about 20 μm and about 100 μm.

Blasting parameters include pressure, angle of impingement, distance to the part surface and duration. In some embodiments, angle of impingement can range from about 10 degrees to about 90 degrees, i.e., the particles impinge the coating surface at an angle ranging from about 10 degrees to about 90 degrees. Suitable pressures can range from 30-55 pounds per square inch (psi) at a distance to the coated surface of 1-6 inches. Further, duration of the blasting can generally range from 1-10 seconds or longer. Blasting can be generally administered over the surface area of the coating or can be applied to select locations such as in a workpiece contact area of the cutting tool. A workpiece contact area can be a honed region of the cutting tool.

In other embodiments, a coating is subjected to a polishing post-coat treatment. Polishing can be administered with paste of appropriate diamond or ceramic grit size. Grit size of the paste, in some embodiments, ranges from 1 μm to 10 μm. In one embodiment, a 5-10 μm diamond grit paste is used to polish the coating. Further, grit paste can be applied to the CVD coating by any apparatus not inconsistent with the objectives of the present invention, such as brushes. In one embodiment, for example, a flat brush is used to apply grit paste to the CVD coating in a workpiece contact area of the cutting tool.

A coating described herein can be blasted or polished for a time period sufficient to achieve a desired surface roughness (Rₐ) and/or other parameters such as reducing residual tensile stress in the coating. In some embodiments, a coating subjected to post-coat treatment has a surface roughness (Rₐ) selected from Table I.

TABLE I
Post-Coat Surface Roughness (Rₐ)
Coating Surface Roughness (Rₐ) - nm

≤500
≤250
<200
10-250
50-175
25-150

Coating surface roughness can be determined by optical profilometry using WYKOR NT-Series Optical Profilers commercially available from Veeco Instruments, Inc. of Plainview, New York. Coating surface roughness can be determined via optical metrology with instrumentation commercially available from Bruker Alicona of Itasca, IL.

Further, a post-coat treatment, in some embodiments, does not remove one or more outer layers of the coating. In some embodiments, for example, a post-coat treatment does not remove an outer layer of TiN, TiCN and/or TiOCN. Alternatively, a post-coat treatment can remove or partially remove one or more outer layers, such as TiN, TiCN and TiOCN to expose the underlying polycrystalline α-Al₂O₃ layer.

In another aspect, methods of making coated cutting tools comprising one or more refractory layers of polycrystalline α-Al₂O₃ are described herein. In some embodiments, a method comprises depositing a polycrystalline α-Al₂O₃ layer from a gaseous reaction mixture comprising H₂, CO, CO₂, H₂S, HCl, AlCl₃ wherein the volume ratio of CO₂ and H₂S in the CVD reaction chamber lies within the range of 5<CO₂/H₂S<10, and the deposited polycrystalline α-Al₂O₃ layer has a length of Σ3 type of grain boundaries as measured using EBSD more than 0% but less than 10% of the total length of all grain boundaries and having texture coefficients (TC) greater than 6 for the (006) growth direction and greater than 5 for the (0 0 12) growth direction as set forth above. In some embodiments, the deposited polycrystalline α-Al₂O₃ layer(s) can have any properties described hereinabove. In some embodiments, the ratio of CO/H₂S >2 in methods described herein.

These and other embodiments are further illustrated in the following non-limiting examples.

### Example 1—Coated Cutting Tools

Sintered cemented carbide cutting inserts of ANSI geometry CNMG433RP were provided having the composition of Table II.

TABLE II
Sintered Cemented Carbide Substrate Composition

| Component | Weight Percent |
|---|---|
| Cobalt | 6.5-7.5 |
| Group IV-VI Carbides | 5-7 |
| WC | Balance |

The sintered cemented carbide cutting inserts were provided base CVD layers having the composition and architecture provided in Table III.

TABLE III
CVD Coating Architecture

| Layer | Thickness (μm) |
|---|---|
| TiN* | 0.2-0.75 |
| MT-TiCN | 6-10 |
| TiOₓC_{y}N_{z} | 0.5-1 |

*Base layer adjacent to the substrate

The base layers were deposited in a Sucotec CVD furnace commercially available from Oerlikon Balzers. TiN, MT-TiCN, and TiOₓC_{y}N_{z} layers were deposited according to the parameters in Tables IV and V.

TABLE IV
CVD Deposition of Coating Layers

| Process | H₂ | N₂ | TiCl₄ | CH₃CN | CH₄ | AlCl₃ | CO₂ | CO | HCl | H₂S |
|---|---|---|---|---|---|---|---|---|---|---|
| Step | vol. % | vol. % | vol. % | vol. % | vol. % | vol. % | vol. % | vol. % | vol. % | vol. % |
| TiN | Bal. | 36-38 | 0.007-0.010 | — | — | — | — | — | — | — |
| MT—TiCN | Bal. | 16-18 | 0.10-0.15 | 0.001-0.002 | — | — | — | — | — | — |
| HT—TiCN | Bal. | 28-30 | 0.008-0.011 | — | 4.3-4.5 | — | — | — | — | — |
| TiOCN | Bal. | 34-37 | 0.009-0.012 | — | 1.8-2.3 | — | — | 1.3-1.4 | 1.6-1.7 | — |
| TiAlOCN | Bal. | 35-38 | 0.012-0.015 | 0.001-0.003 | — | 0.55-0.65 | — | 4.3-4.5 | — | — |

TABLE V
CVD Deposition Steps

| | | Pressure | Time |
|---|---|---|---|
| Process Step | Temperature | mbar | min. |
| TiN | 850-960 | 60-90 | 10-90 |
| MT-TiCN | 900-940 | 70-100 | 50-400 |
| HT-TiCN | 900-1050 | 60-150 | 30-200 |
| TiOCN | 950-1050 | 200-500 | 30-70 |

The α-Al₂O₃ layers of the samples were deposited at 1000° C. in two steps according to Table VI.

TABLE VI
α-Al₂O₃ layer CVD Deposition

| | Alumina Deposition Step 1 | | | | | | | | |
|---|---|---|---|---|---|---|---|---|---|
| | Temperature | Pressure | Time | Raw material gas composition (vol %) | | | | | |
| Samples | (° C) | (mbar) | (min) | AlCl₃ | HCl | CO | CO₂ | N₂ | H₂ |
| Invention | 1000 | 85 | 10 | 2 | 1.94 | 1.94 | 2.72 | 19.44 | Balance |
| sample A | | | | | | | | | |
| Invention | 1000 | 85 | 10 | 2 | 1.95 | 2.72 | 3.70 | 19.48 | Balance |
| sample B | | | | | | | | | |
| Invention | 1000 | 85 | 10 | 1.98 | 1.93 | 2.31 | 3.27 | 19.26 | Balance |
| sample C | | | | | | | | | |
| Comparative | 1000 | 75 | 60 | 2.43 | 1.70 | 1.70 | 2.95 | 8.5 | Balance |
| sample A | | | | | | | | | |
| | Alumina Deposition Step 2 | | | | | | | | |
| | Temperature | Pressure | Time | Raw material gas composition (vol %) | | | | | |
| Samples | (° C) | (mbar) | (min) | AlCl₃ | HCl | H₂S | CO | CO₂ | H₂ |
| Invention | 1000 | 75 | 645 | 2.04 | 1.98 | 0.45 | 1.98 | 3.56 | Balance |
| sample A | | | | | | | | | |
| Invention | 1000 | 80 | 390 | 2.23 | 2.17 | 0.71 | 3.03 | 5.2 | Balance |
| sample B | | | | | | | | | |
| Invention | 1000 | 75 | 480 | 2.00 | 1.95 | 0.64 | 2.34 | 4.29 | Balance |
| sample C | | | | | | | | | |
| Comparative | 990 | 75 | 460 | 2.36 | 1.65 | 0.31 | 0 | 4.12 | Balance |
| sample A | | | | | | | | | |

For Inventive samples A-C the volume ratio of CO₂ and H₂S in the CVD reaction chamber lies within the range of 5<CO₂/H₂S<10 for the second step. The CO₂/H₂S of Comparative sample A was outside this range. Deposition time for each sample is adjusted to get α-Al₂O₃ layer thickness of about 8 μm. Properties of the polycrystalline α-Al₂O₃ layers of Inventive samples A-C and Comparative sample A are provided in Table VII.

TABLE VII
α-Al₂O₃ layer properties

| | Alumina 23% of all | Alumina TC | Alumina TC |
|---|---|---|---|
| Type | grain boundaries | (0 0 6) | (0 0 12) |
| Invention sample A | 1.1 | 7.67 | 6.86 |
| Invention sample B | 4.17 | 7.46 | 6.52 |
| Invention sample C | 2.63 | 7.7 | 5.80 |
| Comparative sample A | 1.82 | 2.62 | 3.2 |

The coated cutting inserts (Inventive samples A-C and Comparative sample A) were subsequently subjected to metal cutting testing. Metal cutting test conditions are results are provided below.

### Metal Cutting Test Conditions and Results

1) 4340 Steel Turning Flank Wear Resistance
   Cutting parameters—700 sfm/0.012 ipr/0.1 doc/Flood

| Tool Description | Tool Life (Rep 1) | Tool Life (Rep 2) |
|---|---|---|
| Invention sample A | 13.5 NW | 13.0 NW |
| Invention sample B | 13.5 MW | 13.9 NW |
| Invention sample C | 16.4 MW | 16.1 NW |
| Comparative sample A | 7.0 NW | 6.0 NW |

2) 1045 Steel Turning Crater Wear Resistance
   Cutting parameters—1200 sfm/0.013 ipr/0.08 doc/Flood

| Tool Description | Tool Life (Rep 1) | Tool Life (Rep 2) |
|---|---|---|
| Invention sample A | 29 NW | 27.6 NW |
| Invention sample B | 32.9 NW | 41.3 MW |
| Invention sample C | 27.0 NW | 30.7 NW |
| Comparative sample A | 13.4 NW | 12.8 NW |

3) 4140 Steel Interrupted Cut Chipping Resistance
   Cutting parameters—500 sfm/0.010 ipr/0.100 doc/Flood

| Tool Description | Tool Life (Rep 1) | Tool Life (Rep 2) |
|---|---|---|
| Invention sample A | 21.9 MW | 26.8 MW |
| Invention sample B | 21.3 MW | 28.4 MW |
| Invention sample C | 22.7 NW | 18.6 MW |
| Comparative sample A | 4.4 NW | 8.7 MW |

4) Ductile Cast Iron Face Cycle Interrupted Cut Coating Flaking Test
   Cutting parameters—895 sfm/0.012 ipr/0.08 doc/Flood

| | Tool Life as % of | Tool Life as % of |
|---|---|---|
| | coating remaining | coating remaining |
| | on rake face | on rake face |
| Tool Description | (Rep 1) | (Rep 2) |
| Invention sample A | 80 | 85 |
| Invention sample B | 58 | 47 |
| Invention sample C | 77 | 60 |
| Comparative sample A | 30 | 35 |

As provided in the metal cutting testing, Inventive samples A-C significantly outperformed Comparative sample A across multiple workpieces and cutting applications, including turning and interrupted cutting.

Various embodiments of the invention have been described in fulfillment of the various objects of the invention. It should be recognized that these embodiments are merely illustrative of the principles of the present invention. Numerous modifications and adaptations thereof will be readily apparent to those skilled in the art without departing from the spirit and scope of the invention.

1. A coated cutting tool comprising:
a substrate, and
a coating adhered to the substrate, the coating comprising a layer of polycrystalline α-Al₂O₃ deposited by chemical vapor deposition (CVD), the polycrystalline α-Al₂O₃ layer having a length of Σ3 type of grain boundaries as measured using EBSD more than 0% but less than 10% of the total length of all grain boundaries and having texture coefficients (TC) greater than 6 for the (006) growth direction and greater than 5 for the (0 0 12) growth direction, the texture coefficients being defined as:
$$TC ( hkl ) = \frac{I ( hkl )}{{I}_{o} ( hkl )} {\{ \frac{1}{n} \sum \frac{I ( hkl )}{{I}_{o} ( hkl )} \}}^{- 1}$$
where
I(hkl)=measured intensity of the (hkl) reflection
Iₒ(hkl)=standard intensity of the (hkl) reflection according to International Center for Diffraction Data (ICDD) card 43-1484
n=number of reflections used in the TC calculation
(hkl) reflections used in the TC calculation are:
(012), (104), (110), (006), (113), (202), (024) and (116) to calculate TC (006) or
(012), (104), (110), (113), (116), (300) and (0 0 12) to calculate TC (0012).

2. The coated cutting tool of claim 1, wherein the length of Σ3 type of grain boundaries is 1% to 8% of the total length of all grain boundaries.

3. The coated cutting tool of claim 1, wherein the length of Σ3 type of grain boundaries is 2% to 5% of the total length of all grain boundaries.

4. The coating cutting tool of claim 1, wherein the TC is from 6.5-7.8 for the (006) growth direction.

5. The coated cutting tool of claim 4, wherein the TC is from 5.5-6.5 for the (0 0 12) growth direction.

6. The coated cutting tool of claim 1, wherein the polycrystalline α-Al₂O₃ layer comprises columnar grains.

7. The coated cutting tool of claim 6, wherein the columnar grains have an average grain width of 0.1 μm to 3 μm.

8. The coated cutting tool of claim 6, wherein the columnar grains have an average grain width of 0.5 μm to 4.5 μm.

9. The coated cutting tool of claim 6, wherein the columnar grains have an average grain width of 1 μm to 2 μm.

10. The coated cutting tool of claim 1, wherein at least 5% of all grain boundaries in the polycrystalline α-Al₂O₃ layer have a misorientation angle less than 15 degrees.

11. The coated cutting tool of claim 10, wherein 5% to 20% of all grain boundaries in the polycrystalline α-Al₂O₃ layer have a misorientation of 2-5 degrees and at least 5% of all grain boundaries in the polycrystalline α-Al₂O₃ layer have a misorientation of greater than 5 degrees up to 15 degrees.

12. The coated cutting tool of claim 11, wherein 16-20% of all grain boundaries of polycrystalline α-Al₂O₃ layer have a misorientation of 2-5 degrees.

13. The coated cutting tool of claim 1, wherein the polycrystalline α-Al₂O₃ layer has a thickness of 1-20 μm.

14. The coated cutting tool of claim 1, wherein the polycrystalline α-Al₂O₃ layer has a residual stress of 20-400 MPa.

15. The coated cutting tool of claim 1, wherein the coating further comprises one or more inner layers between the polycrystalline α-Al₂O₃ layer and the substrate.

16. The coated cutting tool of claim 15, wherein the one or more inner layers comprise one or more metallic elements selected from the group consisting of aluminum and metallic elements of Groups IVB, VB and VIB of the Periodic Table and one or more non-metallic elements selected from the group consisting of non-metallic elements of Groups IIIA, IVA, VA and VIA of the Periodic Table.

17. The coated cutting tool of claim 1, wherein the substrate comprises cemented carbide comprising metallic binder in an amount of 1-15 weight percent.

18. A method comprising:
depositing a polycrystalline α-Al₂O₃ layer from a gaseous reaction mixture comprising H₂, CO, CO₂, H₂S, HCl, AlCl₃ wherein the volume ratio of CO₂ and H₂S in the CVD reaction chamber lies within the range of 5<CO₂/H₂S<10, and the deposited polycrystalline α-Al₂O₃ layer has a length of Σ3 type of grain boundaries as measured using EBSD more than 0% but less than 10% of the total length of all grain boundaries and having texture coefficients (TC) greater than 6 for the (006) growth direction and greater than 5 for the (0 0 12) growth direction, the texture coefficients being defined as:
$$TC ( hkl ) = \frac{I ( hkl )}{{I}_{o} ( hkl )} {\{ \frac{1}{n} \sum \frac{I ( hkl )}{{I}_{o} ( hkl )} \}}^{- 1}$$
where
I(hkl)=measured intensity of the (hkl) reflection
Iₒ(hkl)=standard intensity of the (hkl) reflection according to International Center for Diffraction Data (ICDD) card 43-1484
n=number of reflections used in the TC calculation
(hkl) reflections used in the TC calculation are:
(012), (104), (110), (006), (113), (202), (024) and (116) to calculate TC (006) or
(012), (104), (110), (113), (116), (300) and (0 0 12) to calculate TC (0012).

19. The method of claim 18, wherein the length of Σ3 type of grain boundaries is 1% to 8% of the total length of all grain boundaries.

20. The method of claim 18, the polycrystalline α-Al₂O₃ layer comprises columnar grains having an average width of 0.1 μm to 3 μm.
